(19) United States
(12) Patent Application Publication
(10) Pub. No.: US 2026/0348005 A1
(43) Pub. Date: Nov. 5, 2026

(54) ALUMINUM FLUORIDE ETCH FROM ALUMINUM-CONTAINING COMPONENTS

(71) Applicant: Lam Research Corporation, Fremont, CA (US)

(72) Inventors: Byung Seok Kwon, Tigard, OR (US); Kyle Cheng, Milpitas, CA (US); Yanhui Huang, Sherwood, OR (US); Fayaz A. Shaikh, Lake Oswego, OR (US); Nick Ray Linebarger, JR., Tualatin, OR (US); Daniel Boatright, Estacada, OR (US); Sudhir Chopra, San Jose, CA (US); Ruisong Wang, Tigard, OR (US)

(21) Appl. No.: 19/486,868

(22) PCT Filed: May 20, 2024
(86) PCT No.: PCT/US2024/030270

§ 371 Date: Nov. 21, 2025

Related U.S. Application Data
(60) Provisional application No. 63/504,077, filed on May 24, 2023.

(51) Int. Cl. C23C 16/44; C23G 1/22

(52) U.S. Cl. CPC C23C 16/4407; C23G 1/22

(57) ABSTRACT

A method for treating aluminum fluoride or aluminum oxyfluoride includes providing a fluorine-containing species into a process chamber in which one or more components are located, removing the one or more components out of the process chamber, and cleaning the one or more components with an etch composition. The one or more components include aluminum, aluminum alloy, or aluminum-containing material.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

In a semiconductor device fabrication process, various materials are deposited on interior surfaces of a process chamber or the surfaces of components in the process chamber forming wall deposits. Wall deposits may be a source of contamination for a substrate in a subsequent operation, and the thickness may increase with repeated numbers of operations. Wall deposits may be removed from the interior surfaces of the process chamber without or the surfaces of components in the process chamber.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect involves a method of cleaning aluminum fluoride or aluminum oxyfluoride, where the method includes providing a fluorine-containing species into a process chamber in which one or more components are located, removing the one or more components out of the process chamber; and cleaning the one or more components with an etch composition, wherein the one or more components includes aluminum, aluminum alloy, or aluminum-containing material.

In some embodiments, cleaning the one or more components includes etching the aluminum fluoride or aluminum oxy fluoride from a surface of the one or more components.

In some embodiments, cleaning the one or more components includes separating the aluminum fluoride or aluminum oxyfluoride from a surface of the one or more components.

In some embodiments, the one or more components includes a pedestal, a showerhead, or a showerhead-pedestal.

In some embodiments, the etch composition includes a hydroxyl group-containing solution including potassium hydroxide, sodium hydroxide, ammonium hydroxide, tetramethylammonium hydroxide, tetraethylammonium hydroxide, or combinations thereof.

In some embodiments, a concentration of the hydroxyl group-containing solution is about 0.1 to about 45 percent weight/volume.

In some embodiments, a concentration of the hydroxyl group-containing solution is about 0.5 to about 30 percent weight/volume.

In some embodiments, the concentration of the hydroxyl group-containing solution is about 1 to about 20 percent weight/volume.

In some embodiments, the concentration of the hydroxyl group-containing solution is about 1.5 to about 10 percent weight/volume.

In some embodiments, the concentration of the hydroxyl group-containing solution is about 2 to about 7 percent weight/volume.

In some embodiments, the one or more components are cleaned for about 0.1 to about 45 minutes.

In some embodiments, the one or more components are cleaned for about 1 to about 30 minutes.

In some embodiments, the one or more components are cleaned for about 1 to about 10 minutes.

In some embodiments, the one or more components are cleaned for about 5 to about 25 minutes.

In some embodiments, the one or more components are cleaned for about 8 to about 20 minutes.

In some embodiments, the one or more components are cleaned for about 10 to about 15 minutes.

In some embodiments, wherein the fluorine-containing species includes nitrogen fluoride plasma.

The method further includes depositing a film on a substrate in the process chamber prior to providing the fluorine-containing species into the process chamber.

The method further includes removing the substrate out of the process chamber after depositing the film.

The method further includes providing the one or more components in the process chamber after cleaning the one or more components with the etch composition.

Another aspect involves a method of etching in a process chamber, where the method includes exposing the surface of the component comprising aluminum fluoride or aluminum oxyfluoride to a fluorine-containing species, wherein the surface of the component includes aluminum, aluminum alloy, or aluminum-containing materials, and exposing the aluminum fluoride or aluminum oxyfluoride to an etch composition, wherein the etch composition includes a hydroxyl group-containing solution.

In some embodiments, the component includes a pedestal, a showerhead, or a showerhead-pedestal.

In some embodiments, exposing the surface of the component to the fluorine-containing species includes forming the aluminum fluoride or the aluminum oxy fluoride on the surface of the component.

In some embodiments, wherein exposing the aluminum fluoride or the aluminum oxyfluoride to the etch composition includes soaking the component in the etch composition.

In some embodiments, exposing the surface of the component to the etch composition includes soaking the component in the etch composition.

In some embodiments, the fluorine-containing species includes nitrogen fluoride plasma.

The method further includes, prior to providing the fluorine-containing species, exposing the surface of the component to a precursor, thereby forming a silicon-containing film on the surface of the component.

The method further includes providing the one or more components in the process chamber after exposing the aluminum fluoride to the etch composition.

In some embodiments, the etch composition includes potassium hydroxide, sodium hydroxide, ammonium hydroxide, tetramethylammonium hydroxide, tetraethylammonium hydroxide, or combinations thereof.

In some embodiments, the concentration of the etch composition is about 0.1 to about 45 percent weight/volume.

In some embodiments, the concentration of the etch composition is about 0.5 to about 30 percent weight/volume.

In some embodiments, the concentration of the etch composition is about 1 to about 20 percent weight/volume.

In some embodiments, the concentration of the etch composition is about 1.5 to about 10 percent weight/volume.

In some embodiments, the concentration of the etch composition is about 2 to about 7 percent weight/volume.

In some embodiments, the component is exposed for about 0.1 to about 45 minutes.

In some embodiments, the component is exposed for about 1 to about 30 minutes.

In some embodiments, the component is exposed for about 1 to about 10 minutes.

In some embodiments, the component is exposed for about 5 to about 25 minutes.

In some embodiments, the component is exposed for about 8 to about 20 minutes.

In some embodiments, the component is exposed for about 10 to about 15 minutes.

Still another aspect involves a method of cleaning a component, where the method includes providing a component including an aluminum-containing surface, and cleaning the component using a hydroxyl-containing composition.

In some embodiments, cleaning the component includes soaking the component in the hydroxyl-containing composition.

In some embodiments, the component includes a pedestal, a showerhead, or a showerhead-pedestal.

In some embodiments, the hydroxyl-containing composition includes potassium hydroxide, sodium hydroxide, ammonium hydroxide, tetramethylammonium hydroxide, tetraethylammonium hydroxide, or combinations thereof.

In some embodiments, a concentration of the hydroxyl group-containing solution is about 0.1 to about 45 percent weight/volume.

In some embodiments, a concentration of the hydroxyl group-containing solution is about 0.5 to about 30 percent weight/volume.

In some embodiments, the concentration of the hydroxyl group-containing solution is about 1 to about 20 percent weight/volume.

In some embodiments, the concentration of the hydroxyl group-containing solution is about 1.5 to about 10 percent weight/volume.

In some embodiments, the concentration of the hydroxyl group-containing solution is about 2 to about 7 percent weight/volume.

Still yet another aspect involves an apparatus, the apparatus including a process chamber including one or more aluminum-containing components in the interior of the process chamber, a first gas source fluidly coupled to the process chamber, a second gas source fluidly coupled to the process chamber, a plasma source fluidly coupled to the process chamber, and a controller configured to: (a) cause a precursor in the process chamber to form a film on the substrate; and (b) cause a fluorine-containing species in the process chamber.

In some embodiments, the one or more components is made of aluminum, aluminum alloy, or aluminum-containing material.

In some embodiments, the one or more components includes a pedestal, a showerhead, or a showerhead-pedestal.

In some embodiments, the film includes silicon oxide, silicon nitride, doped or undoped polysilicon, or doped or undoped silicon carbide.

In some embodiments, the fluorine-containing species includes fluorine-containing source gases, fluorine-containing plasma, or mixture thereof.

In some embodiments, the fluorine-containing source gas includes nitrogen trifluoride (NF₃), molecular fluorine (F₂), carbon tetrafluoride (CF₄₎, carbon hexafluoride (C₂F₆), xenon difluoride (XeF₂), fluoromethane (CH₃F), difluoromethane (CH₂F₂), tetrafluoroethylene (C₂F₄), hexafluoroethane (CF₆), octafluoropropane (C₃F₈), sulfur hexafluoride (SF₆), or combinations thereof.

In some embodiments, the plasma source includes a remote plasma source.

These and other aspects are described further below with reference to the drawings.

### BRIEF DESCRIPTION OF THE DRAWINGS

FIG. 1 is a flow chart of an example method of cleaning surfaces of one or more components in a process chamber according to some embodiments.

FIG. 2 is a flow chart of an example method of cleaning a component according to some embodiments.

FIG. 3A-3E are scanning electron micrograph images showing the etching of aluminum fluoride from the surfaces of a component with etch time according to some embodiments.

FIG. 4 is a graph illustrating the size range and number of aluminum fluoride particles on the backside of a substrate prior to and after cleaning a showerhead-pedestal underneath the substrate according to some embodiments.

FIGS. 5A and 5B show block diagrams of an example substrate processing system according to some embodiments.

FIG. 6 shows a schematic of an example process system that may be used to perform the methods described herein.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### Terminology

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl (—C(O)H), acetyl (Ac or —C(O)Me), propionyl, isobutyryl, butanoyl, and the like. In some embodiments, the acyl or alkanoyl group is —C(O)—R, in which R is hydrogen, an aliphatic group, or an aromatic group, as defined herein.

By “alkanoyloxy” is meant an alkanoyl group, as defined herein, attached to the parent molecular group through an oxy group, as defined herein. This group is exemplified by acetoxy (—OAc or —OC(O)Me). In some embodiments, the alkanoyloxy group is —OC(O)—R, in which R is hydrogen, an aliphatic group, or an aromatic group, as defined herein.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight-and branched-chain arrangements, and all stereo and position isomers as well. An aliphatic group is unsubstituted or substituted, e.g., by a functional group described herein. For example, the aliphatic group can be substituted with one or more substitution groups, as described herein for alkyl.

By “aliphatic-carbonyl” is meant an aliphatic group that is or can be coupled to a compound disclosed herein, wherein the aliphatic group is or becomes coupled through a carbonyl group (—C(O)—). In some embodiments, the aliphatic-carbonyl group is —C(O)—R, in which R is an optionally substituted aliphatic group, as defined herein.

By “aliphatic-carbonyloxy” is meant an aliphatic group that is or can be coupled to a compound disclosed herein, wherein the aliphatic group is or becomes coupled through a carbonyloxy group (—OC(O)—). In some embodiments, the aliphatic-carbonyloxy group is —OC(O)—R, in which R is an optionally substituted aliphatic group, as defined herein.

By “aliphatic-oxy” is meant an aliphatic group that is or can be coupled to a compound disclosed herein, wherein the aliphatic group is or becomes coupled through an oxy group (—C(O)—). In some embodiments, the aliphatic-oxy group is —O—R, in which R is an optionally substituted aliphatic group, as defined herein.

By “aliphatic-oxycarbonyl” is meant an aliphatic group that is or can be coupled to a compound disclosed herein, wherein the aliphatic group is or becomes coupled through an oxycarbonyl group (—C(O)O—). In some embodiments, the aliphatic-oxycarbonyl group is —C(O)O—R, in which R is an optionally substituted aliphatic group, as defined herein.

By “alkyl-aryl,” “alkenyl-aryl,” and “alkynyl-aryl” is meant an alkyl, alkenyl, or alkynyl group, respectively and as defined herein, that is or can be coupled (or attached) to the parent molecular group through an aryl group, as defined herein. The alkyl-aryl, alkenyl-aryl, and/or alkynyl-aryl group can be substituted or unsubstituted. For example, the alkyl-aryl, alkenyl-aryl, and/or alkynyl-aryl group can be substituted with one or more substitution groups, as described herein for alkyl and/or aryl. Exemplary unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ aryl). Exemplary unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂₋₆ alkenyl-C₄₋₁₈ aryl). Exemplary unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₁₈ aryl). In some embodiments, the alkyl-aryl group is -L-R, in which L is an aryl group or an arylene group, as defined herein, and R is an alkyl group, as defined herein. In some embodiments, the alkenyl-aryl group is -L-R, in which L is an aryl group or an arylene group, as defined herein, and R is an alkenyl group, as defined herein. In some embodiments, the alkynyl-aryl group is -L-R, in which L is an aryl group or an arylene group, as defined herein, and R is an alkynyl group, as defined herein.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An exemplary alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl. Non-limiting alkenyl groups include allyl (All), vinyl (Vi), 1-butenyl, 2-butenyl, and the like.

By “alkoxy” is meant —OR, where R is an optionally substituted aliphatic group, as described herein. Exemplary alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkoxyalkyl” is meant an alkyl group, as defined herein, which is substituted with an alkoxy group, as defined herein. Exemplary unsubstituted alkoxyalkyl groups include between 2 to 12 carbons (C₂₋₁₂ alkoxyalkyl), as well as those having an alkyl group with 1 to 6 carbons and an alkoxy group with 1 to 6 carbons (i.e., C₁₋₆ alkoxy-C₁₋₆ alkyl). In some embodiments, the alkoxyalkyl group is -L-O—R, in which each of L and R is, independently, an alkyl group, as defined herein.

By “alkoxycarbonyl” is meant —C(O)—OR, where R is an optionally substituted aliphatic group, as described herein. In particular embodiments, the alkoxycarbonyl group is —C(O)—Oak, in which Ak is an alkyl group, as defined herein. The alkoxycarbonyl group can be substituted or unsubstituted. For example, the alkoxycarbonyl group can be substituted with one or more substitution groups, as described herein for alkyl. Exemplary unsubstituted alkoxycarbonyl groups include C₂₋₃, C₂₋₆, C₂₋₇, C₂₋₁₂, C₂₋₁₆, C₂₋₁₈, C₂₋₂₀, or C₂₋₂₄ alkoxycarbonyl groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An exemplary alkyl includes a branched or unbranched saturated hydrocarbon group of 1 to 24 carbon atoms, such as methyl (Me), ethyl (Et), n-propyl (nPr), iso-propyl (iPr), n-butyl (nBu), iso-butyl (iBu), sec-butyl (sBu), tert-butyl (tBu), pentyl (Pe), n-pentyl (nPe), isopentyl (iPe), s-pentyl (sPe), neopentyl (neoPe), tert-pentyl (tPe), hexyl (Hx), heptyl (Hp), octyl (Oc), nonyl (Nn), decyl (De), dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g.—CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) N-protected amino; (18) nitro (e.g., —NO₂); (19) oxo (e.g., ═O); (20) C₁₋₆ thioalkyl (e.g., —S—R, in which R is alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆ , C₁₋₁₂, C₁₋₁₆, C₁₋₁₈, C₁₋₂₀, or C₁₋₂₄ alkyl group.

By “alkylene,” “alkenylene,” or “alkynylene” is meant a multivalent (e.g., bivalent) form of an alkyl, alkenyl, or alkynyl group, respectively, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. In other embodiments, the alkylene group is a C₂₋₃, C₂₋₆, C₂₋₁₂, C₂₋₁₆, C₂₋₁₈, C₂₋₂₀, or C₂₋₂₄ alkenylene or alkynylene group. The alkylene, alkenylene, or alkynylene group can be branched or unbranched. The alkylene, alkenylene, or alkynylene group can also be substituted or unsubstituted. For example, the alkylene, alkenylene, or alkynylene group can be substituted with one or more substitution groups, as described herein for alkyl.

By “alkylsulfinyl” is meant an alkyl group, as defined herein, attached to the parent molecular group through an —S(O)— group. In some embodiments, the unsubstituted alkylsulfinyl group is a C₁₋₆ or C₁₋₁₂ alkylsulfinyl group. In other embodiments, the alkylsulfinyl group is —S(O)—R, in which R is an alkyl group, as defined herein.

By “alkylsulfinylalkyl” is meant an alkyl group, as defined herein, substituted by an alkylsulfinyl group. In some embodiments, the unsubstituted alkylsulfinylalkyl group is a C₂₋₁₂ or C₂₋₂₄ alkylsulfinylalkyl group (e.g., C₁₋₆ alkylsulfinyl-C₁₋₆ alkyl or C₁₋₁₂ alkylsulfinyl-C₁₋₁₂ alkyl). In other embodiments, the alkylsulfinylalkyl group is -L-S(O)—R, in which each of L and R is, independently, an alkyl group, as defined herein.

By “alkylsulfonyl” is meant an alkyl group, as defined herein, attached to the parent molecular group through an —SO₂— group. In some embodiments, the unsubstituted alkylsulfonyl group is a C₁₋₆ or C₁₋₁₂ alkylsulfonyl group. In other embodiments, the alkylsulfonyl group is —SO₂—R, where R is an optionally substituted alkyl (e.g., as described herein, including optionally substituted C₁₋₁₂ alkyl, haloalkyl, or perfluoroalkyl).

By “alkylsulfonylalkyl” is meant an alkyl group, as defined herein, substituted by an alkylsulfonyl group. In some embodiments, the unsubstituted alkylsulfonylalkyl group is a C₂₋₁₂ or C₂₋₂₄ alkylsulfonylalkyl group (e.g., C₁₋₆ alkylsulfonyl-C₁₋₆ alkyl or C₁₋₁₂ alkylsulfonyl-C₁₋₁₂ alkyl). In other embodiments, the alkylsulfonylalkyl group is -L-SO₂—R, in which each of L and R is, independently, an alkyl group, as defined herein.

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An exemplary alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “ambient temperature” is meant a temperature ranging from 16 °C to 26 °C, such as from 19 °C to 25 °C or from 20 °C to 25 °C.

By “amide” is mean —C(O)NR¹R² or —NHCOR¹, where each of R¹ and R² is, independently, selected from hydrogen, aliphatic, heteroaliphatic, aromatic, as defined herein, or any combination thereof, or where R¹ and R², taken together with the nitrogen atom to which each are attached, can form a heterocyclyl group, as defined herein.

By “amino” is meant —NR¹R², where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R¹ and R² can be taken together, with the nitrogen atom to which each is attached, to form an optionally substituted heterocyclyl.

By “aminoalkyl” is meant an alkyl group, as defined herein, substituted by an amino group, as defined herein. In some embodiments, the aminoalkyl group is -L-NR¹R², in which L is an alkyl group, as defined herein, and each of R¹ and R² is, independently, selected from hydrogen, aliphatic, heteroaliphatic, or aromatic, as defined herein, or any combination thereof, or R¹ and R², taken together with the nitrogen atom to which each are attached, can form a heterocyclyl group, as defined herein. In other embodiments, the aminoalkyl group is -L-C(NR¹R²)(R³)—R⁴, in which L is a covalent bond or an alkyl group, as defined herein; each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein, and each of R³ and R⁴ is, independently, Hor alkyl, as defined herein.

By “aminooxy” is meant an oxy group, as defined herein, substituted by an amino group, as defined herein. In some embodiments, the aminooxy group is —O—NR¹R², in which each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane a-electrons corresponds to the Huckel rule (4n+2). The point of attachment to the parent structure typically is through an aromatic portion of the condensed ring system. An aromatic group is unsubstituted or substituted, e.g., by a functional group described herein. For example, the aromatic group can be substituted with one or more substitution groups, as described herein for alkyl and/or aryl.

By “aromatic-carbonyl” is meant an aromatic group that is or can be coupled to a compound disclosed herein, wherein the aromatic group is or becomes coupled through a carbonyl group (—C(O)—). In some embodiments, the aromatic-carbonyl group is —C(O)—R, in which R is an optionally substituted aromatic group, as defined herein.

By “aromatic-carbonyloxy” is meant an aromatic group that is or can be coupled to a compound disclosed herein, wherein the aromatic group is or becomes coupled through a carbonyloxy group (—OC(O)—). In some embodiments, the aromatic-carbonyloxy group is —OC(O)—R, in which R is an optionally substituted aromatic group, as defined herein.

By “aromatic-oxy” is meant an aromatic group that is or can be coupled to a compound disclosed herein, wherein the aromatic group is or becomes coupled through an oxy group (—O—). In some embodiments, the aromatic-oxy group is —O—R, in which R is an optionally substituted aromatic group, as defined herein.

By “aromatic-oxycarbonyl” is meant an aromatic group that is or can be coupled to a compound disclosed herein, wherein the aromatic group is or becomes coupled through an oxycarbonyl group (—C(O)O—). In some embodiments, the aromatic-carbonyl group is —C(O)O—R, in which R is an optionally substituted aromatic group, as defined herein.

By “aryl” is meant an aromatic carbocyclic group including at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Exemplary aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O-R, in which R is C₁₋₆ alkyl); (4) C₁₋₆ alkoxy-C₁₋₆ alkyl (e.g., -L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., -L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g., -L-SO₂-R, in which each of L and R is, independently, C₁₋₆ alkyl); (9) aryl; (10) amino (e.g., NR¹R², where each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein); (11) C₁₋₆ aminoalkyl (e.g., -L¹-NR¹R² or -L²-C(NR¹R²)(R³)-R⁴, in which L¹ is C₁₋₆ alkyl; L² is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein; and each of R³ and R⁴ is, independently, H or C₁₋₆ alkyl); (12) heteroaryl; (13) C₄₋₁₈ aryl-C₁₋₆ alkyl (e.g., -L-R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., —CN); (17) C₁₋₆ azidoalkyl (e.g., -L-N₃, in which L is C₁₋₆ alkyl); (18) aldehyde (e.g., —C(O)H); (19) aldehyde-C₁₋₆ alkyl (e.g., -L-C(O)H, in which L is C₁₋₆ alkyl); (20) C₃₋₈ cycloalkyl; (21) C₃₋₈ cycloalkyl-C₁₋₆ alkyl (e.g., -L-R, in which L is C₁₋₆ alkyl and R is C₃₋₈ cycloalkyl); (22) halo; (23) C₁₋₆ haloalkyl (e.g., -L¹-X or -L²-C(X)(R¹)-R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5-, 6- or 7-membered ring containing one, two, three, or four non-carbon. heteroatoms); (25) heterocyclyloxy (e.g., —O—R, in which R is heterocyclyl, as defined herein); (26) heterocyclyloyl (e.g., —C(O)—R, in which R is heterocyclyl, as defined herein): (27) hydroxyl (—OH); (28) C₁₋₆ hydroxyalkyl (e.g., -L¹-OH or -L²-C(OH)(R¹)—R², in which L¹ is C₁₋₆ alkyl; L¹ is a covalent bond or alkyl; and each of R¹ and R² is, independently, H or C₁₋₆ alkyl, as defined herein); (29) nitro; (30) C₁₋₆ nitroalkyl (e.g., -L¹-NO or -L²-C(NO)(R¹)-R², in which L¹ is C₁₋₆ alkyl; L² is a covalent bond or alkyl; and each of R¹ and R² is, independently, H or C₁₋₆ alkyl, as defined herein): (31) N-protected amino; (32) N-protected amino-C₁₋₆ alkyl; (33) oxo (e.g., ═O); (34) C₁₋₆ thioalkyl (e.g., —S—R, in which R is C₁₋₆ alkyl); (35) thio-C₁₋₆ alkoxy-C₁₋₆ alkyl (e.g., -L-S—R, in which each of L and R is, independently, C₁₋₆ alkyl); (36) —(CH₂), CO₂R¹, where r is an integer of from zero to four, and R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (37) —(CH₂)ᵣCONR¹R² , where r is an integer of from zero to four and where each R¹ and R² is independently selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (38) —(CH₂)ᵣSO₂R¹, where r is an integer of from zero to four and where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (39) —(CH₂), SO₂NR¹R², where r is an integer of from zero to four and where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “aryl-alkyl,” “aryl-alkenyl,” and “aryl-alkynyl” is meant an aryl group, as defined herein, that is or can be coupled (or attached) to the parent molecular group through an alkyl, alkenyl, or alkynyl group, respectively, as defined herein. The aryl-alkyl, aryl-alkenyl, and/or aryl-alkynyl group can be substituted or unsubstituted. For example, the aryl-alkyl, aryl-alkenyl, and/or aryl-alkynyl group can be substituted with one or more substitution groups, as described herein for aryl and/or alkyl. Exemplary unsubstituted aryl-alkyl groups are of from 7 to 16 carbons (C₇₋₁₆ aryl-alkyl), as well as those having an aryl group with 4 to 18 carbons and an alkyl group with 1 to 6 carbons (i.e., C₄₋₁₈ aryl-C₁₋₆ alkyl). Exemplary unsubstituted aryl-alkenyl groups are of from 7 to 16 carbons (C₇₋₁₆ aryl-alkenyl), as well as those having an aryl group with 4 to 18 carbons and an alkenyl group with 2 to 6 carbons (i.e., C₄₋₁₈ aryl-C₂₋₆ alkenyl). Exemplary unsubstituted aryl-alkynyl groups are of from 7 to 16 carbons (C₇₋₁₆ aryl-alkynyl), as well as those having an aryl group with 4 to 18 carbons and an alkynyl group with 2 to 6 carbons (i.e., C₄₋₁₈ aryl-C₂₋₆ alkynyl). In some embodiments, the aryl-alkyl group is -L-R, in which L is an alkyl group or an alkylene group, as defined herein, and R is an aryl group, as defined herein. In some embodiments, the aryl-alkenyl group is -L-R, in which L is an alkenyl group or an alkenylene group, as defined herein, and R is an aryl group, as defined herein. In some embodiments, the aryl-alkynyl group is -L-R, in which L is an alkynyl group or an alkynylene group, as defined herein, and R is an aryl group, as defined herein.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for aryl.

By “arylalkoxy” is meant an aryl-alkyl group, as defined herein, attached to the parent molecular group through an oxygen atom. In some embodiments, the arylalkoxy group is —O-L-R, in which L is an alkyl group, as defined herein, and R is an aryl group, as defined herein.

By “aryloxy” is meant —OR, where R is an optionally substituted aryl group, as described herein. In some embodiments, an unsubstituted aryloxy group is a C₄₋₁₈ or C₆₋₁₈ aryloxy group, In other embodiments, R is an aryl group that is optionally substituted with alkyl, alkanoyl, amino, hydroxyl, and the like.

By “aryloxycarbonyl” is meant an aryloxy group, as defined herein, that is attached to the parent molecular group through a carbonyl group. In some embodiments, an unsubstituted aryloxycarbonyl group is a C₅₋₁₉ aryloxycarbonyl group. In other embodiments, the aryloxycarbonyl group is —C(O)O—R, in which R is an aryl group, as defined herein.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “aryloyloxy” is meant an aryloyl group, as defined herein, that is attached to the parent molecular group through an oxy group. In some embodiments, an unsubstituted aryloyloxy group is a C₅₋₁₉ aryloyloxy group. In other embodiments, the aryloyloxy group is —OC(O)—R, in which R is an aryl group, as defined herein.

By “azido” is meant an —N₃ group.

By “azidoalkyl” is meant an azido group attached to the parent molecular group through an alkyl group, as defined herein. In some embodiments, the azidoalkyl group is -L-N₃, in which L is an alkyl group, as defined herein.

By “azo” is meant an —N═N— group.

By “carbamoyl” is meant an amino group attached to the parent molecular group through a carbonyl group, as defined herein. In some embodiments, the carbamoyl is —C(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbamoyloxy” is meant a carbamoyl group, as defined herein, attached to the parent molecular group through n oxy group, as defined herein. In some embodiments, the carbamoyl is —OC(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbonimidoyl” is meant a —C(NR)— group. In some embodiments, R is selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof. By “carbonyl” is meant a —C(O)— group, which can also be represented as >C═O.

By “carboxyl” is meant a —CO₂H group or an anion thereof.

By “catalyst” is meant a compound, usually present in small amounts relative to reactants, capable of catalyzing a synthetic reaction, as would be readily understood by a person of ordinary skill in the art. In some embodiments, catalysts may include transition metal coordination complex.

By “cyanato” is meant a —OCN group.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant a —O-L-R group, in which L is an alkyl group or an alkylene group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl], and the like. The cycloalkyl group can also be substituted or unsubstituted. For example, the cycloalkyl group can be substituted with one or more groups including those described herein for alkyl. Further, cycloalkyl may include one or more double bonds and/or triple bonds.

By “cycloheteroaliphatic” is meant a heteroaliphatic group, as defined herein, that is cyclic.

By “disilanyl” is meant a group containing an Si—Si bond. In some embodiments, the disilanyl group is a —SiR^{S1}R^{S2}—SiR^{S3}R^{S4}R^{S5} or —SiR^{S1}R^{S2}—SiR^{S3}R^{S4}— group, in which each of R^{S1}, R^{S2}, R^{S3}, R^{S4}, and R^{S5} is, independently, H, optionally substituted aliphatic, optionally substituted heteroaliphatic, optionally substituted aromatic, optionally substituted heteroaromatic, or optionally substituted amino.

By “disulfide” is meant —SSR, where R is selected from hydrogen, aliphatic, heteroaliphatic, haloaliphatic, haloheteroaliphatic, aromatic, as defined herein, or any combination thereof.

By “electron-donating group” is meant a functional group capable of donating at least a portion of its electron density into the ring to which it is directly attached, such as by resonance.

By “electron-withdrawing group” is meant a functional group capable of accepting electron density from the ring to which it is directly attached, such as by inductive electron withdrawal.

By “halo” is meant F, Cl, Br, or I.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —CX₃ group, wherein each X independently can be selected from fluoro, bromo, chloro, or iodo. In some embodiments, the haloalkyl group is -L-X, in which L is an alkyl group, as defined herein, and X is fluoro, bromo, chloro, or iodo. In other embodiments, the haloalkyl group is -L-C(X)(R¹)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaliphatic group is unsubstituted or substituted, e.g., by a functional group described herein. For example, the heteroaliphatic group can be substituted with one or more substitution groups, as described herein for alkyl.

By “heteroaliphatic-carbonyl” is meant a heteroaliphatic group that is or can be coupled to a compound disclosed herein, wherein the heteroaliphatic group is or becomes coupled through a carbonyl group (—C(O)—). In some embodiments, the heteroaliphatic-carbonyl group is —C(O)—R, in which R is an optionally substituted heteroaliphatic group, as defined herein.

By “heteroaliphatic-carbonyloxy” is meant a heteroaliphatic group that is or can be coupled to a compound disclosed herein, wherein the heteroaliphatic group is or becomes coupled through a carbonyloxy group (—OC(O)—). In some embodiments, the heteroaliphatic-carbonyloxy group is —OC(O)—R, in which R is an optionally substituted heteroaliphatic group, as defined herein.

By “heteroaliphatic-oxy” is meant a heteroaliphatic group that is or can be coupled to a compound disclosed herein, wherein the heteroaliphatic group is or becomes coupled through an oxy group (—C(O)—). In some embodiments, the heteroaliphatic-oxy group is —O—R, in which R is an optionally substituted heteroaliphatic group, as defined herein.

By “heteroaliphatic-oxycarbonyl” is meant a heteroaliphatic group that is or can be coupled to a compound disclosed herein, wherein the heteroaliphatic group is or becomes coupled through an oxycarbonyl group (—C(O)O—). In some embodiments, the heteroaliphatic-oxy carbonyl group is —C(O)O—R, in which R is an optionally substituted heteroaliphatic group, as defined herein.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkylene,” “heteroalkenylene,” and “heteroalkynylene” is meant a multivalent (e.g., bivalent) form of a heteroalkyl, heteroalkenyl, or heteroalkynyl group, respectively, as described herein.

By “heteroaromatic” is meant an aromatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group, A heteroaromatic group is unsubstituted or substituted, e.g., by a functional group described herein. For example, the heteroaromatic group can be substituted with one or more substitution groups, as described herein for alkyl and/or aryl.

By “heteroaromatic-carbonyl” is meant a heteroaromatic group that is or can be coupled to a compound disclosed herein, wherein the heteroaromatic group is or becomes coupled through a carbonyl group (—C(O)—). In some embodiments, the heteroaromatic-carbonyl group is —C(O)—R, in which R is an optionally substituted heteroaromatic group, as defined herein.

By “heteroaromatic-carbonyloxy” is meant a heteroaromatic group that is or can be coupled to a compound disclosed herein, wherein the heteroaromatic group is or becomes coupled through a carbonyloxy group (—OC(O)—). In some embodiments, the heteroaromatic-carbonyloxy group is —OC(O)—R, in which R is an optionally substituted heteroaromatic group, as defined herein.

By “heteroaromatic-oxy” is meant a heteroaromatic group that is or can be coupled to a compound disclosed herein, wherein the heteroaromatic group is or becomes coupled through an oxy group (—O—). In some embodiments, the heteroaromatic-oxy group is —O—R, in which R is an optionally substituted heteroaromatic group, as defined herein, By “heteroaromatic-oxycarbonyl” is meant a heteroaromatic group that is or can be coupled to a compound disclosed herein, wherein the heteroaromatic group is or becomes coupled through an oxycarbonyl group (—C(O)O—). In some embodiments, the heteroaromatic-carbonyl group is —C(O)O—R, in which R is an optionally substituted heteroaromatic group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic and/or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An exemplary heteroaryl includes a subset of heterocyclyl groups, as defined herein, which are aromatic, i.e., they contain 4n+2 pi electrons within the mono-or multicyclic ring system.

By “heteroarylene” is meant a multivalent (e.g., bivalent) form of a heteroaryl group, as described herein.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydrazino” is meant —NR¹—NR²R³, where each of R¹, R², and R³ is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where a combination of R¹ and R² or a combination of R² and R³, taken together with the nitrogen atom to which each are attached, can form a heterocyclyl group, as defined herein. In some embodiments, each of R¹, R², or R³ is, independently, H, optionally substituted alkyl, optionally substituted aryl, optionally substituted alkyl-aryl, or optionally substituted aryl-alkyl. In particular embodiments, R² and R³ can be taken together, with the nitrogen atom to which each is attached, to form an optionally substituted heterocyclyl.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is -L-OH, in which L is an alkyl group, as defined herein. In other embodiments, the hydroxyalkyl group is -L-C(OH)(R¹)—R², in which L is a covalent bond or an alkyl group, as defined herein, and each of R¹ and R² is, independently, H or alkyl, as defined herein.

By “imidoyl” is meant a moiety including a carbonimidoyl group. In some embodiments, the imidoyl group is C(NR¹)R², in which each of R¹ and R² is, independently, selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof. In other embodiments, the imidoyl group is —C(NR¹)H, —C(NR)R^{AK}, or —C(NR^{N1})R^{Ar}, in which R¹ is hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, or optionally substituted silyloxy; R^{AK} is an optionally substituted alkyl or an optionally substituted aliphatic; and R^{Ar} is an optionally substituted aryl or an optionally substituted aromatic.

By “imino” is meant a —NR— group. In some embodiments, R is selected from hydrogen, optionally substituted aliphatic, optionally substituted heteroaliphatic, optionally substituted aromatic, or optionally substituted heteroaromatic. In particular embodiments, Ris H, optionally substituted alkyl, optionally substituted alkoxy, optionally substituted aryl, optionally substituted aryloxy, optionally substituted alkyl-aryl, or optionally substituted aryl-alkyl.

By “isocyanato” is meant a —NCO group.

By “isocyano” is meant a —NC group.

By “ketone” is meant —C(O)R or a compound including such a group, where R is selected from aliphatic, heteroaliphatic, aromatic, as defined herein, or any combination thereof. An example of a ketone can include R¹C(O)R, in which each of R and R¹ is, independently, selected from aliphatic, haloaliphatic, haloheteroaliphatic, heteroaliphatic, aromatic, aliphatic-aromatic, heteroaliphatic-aromatic, as defined herein, or any combination thereof.

By “nitro” is meant an —NO₂ group.

By “nitroalkyl” is meant an alkyl group, as defined herein, substituted by one to three nitro groups. In some embodiments, the nitroalkyl group is -L-NO, in which L is an alkyl group, as defined herein. In other embodiments, the nitroalkyl group is -L-C(NO)(R¹)—R², in which L is a covalent bond or an alkyl group, as defined herein, and each of R¹ and R² is, independently, H or alkyl, as defined herein.

By “oxo” is meant an ═O group.

By “oxy” is meant —O—.

By “perfluoroalkyl” is meant an alkyl group, as defined herein, having each hydrogen atom substituted with a fluorine atom. Exemplary perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “salt” is meant an ionic form of a compound or structure (e.g., any formulas, compounds, or compositions described herein), which includes a cation or anion compound to form an electrically neutral compound or structure. Salts are well known in the art. For example, non-toxic salts are described in Berge S. M. et al., “Pharmaceutical salts,” J. Pharm. Sci. 1977 January; 66(1): 1-19; and in “Handbook of Pharmaceutical Salts: Properties, Selection, and Use,” Wiley-VCH, April 2011(2 nd rev. ed., eds. P. H. Stahl and C. G. Wermuth. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphtboate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amino cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “silyl” is meant a —SiR¹R²R³ or —SiR¹R²— group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR²)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR²)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl

By “sulfinyl” is meant an —S(O)— group.

By “sulfo” is meant an —S(O)₂OH group.

By “sulfonyl” or “sulfonate” is meant an —S(O)₂— group or a —SO₂R, where R is selected from hydrogen, aliphatic, heteroaliphatic, haloaliphatic, haloheteroaliphatic, aromatic, as defined herein, or any combination thereof.

By “thioalkyl” is meant an alkyl group, as defined herein, attached to the parent molecular group through a sulfur atom. Exemplary unsubstituted thioalkyl groups include C₁₋₆ thioalkyl. In some embodiments, the thioalkyl group is —S—R, in which R is an alkyl group, as defined herein.

By “thiol” is meant an —SH group.

A person of ordinary skill in the art would recognize that the definitions provided above are not intended to include impermissible substitution pattems (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, 300 mm, or 450 mm. Examples of wafer materials include silicon (Si), gallium arsenide (GaAs), and silicon germanium (SiGe). Besides semiconductor wafers, other workpieces that may take advantage of the disclosed embodiments include various articles such as printed circuit boards, magnetic recording media, magnetic recording sensors, mirrors, optical elements, display devices or components such as backplanes for pixelated display devices, flat-panel displays, micro-mechanical devices and the like. The workpiece may be of various shapes, sizes, and materials.

A “semiconductor device fabrication operation” as used herein is an operation performed during fabrication of semiconductor devices. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition (PVD), chemical vapor deposition (CVD), plasma enhanced chemical vapor deposition (PECVD), atomic layer deposition (ALD), plasma enhanced atomic layer deposition (PEALD), electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

In the present disclosure, the terms “depositing,” and “forming” are used interchangeably. Also, the terms “layer,” “film,” and “thin film” are used interchangeably, One of ordinary skill in the art would understand that “forming” a “layer” in any of many stages of integrated circuit fabrication can refer to “depositing” a “film” or “thin film” by one of various film forming methods such as CVD, PECVD, ALD, or PEALD due to the decreased feature sizes in a semiconductor device.

In the present disclosure, the term “cleaning,” “etching,” and “removing” are used interchangeably. In the context of an etch process, a person of ordinary skill would agree that etching a material from the interior surfaces of a process chamber is equivalent to “cleaning” or “removing” the material from the interior surfaces of the process chamber, thereby leaving the interior surfaces free of the material.

### INTRODUCTION

Semiconductor device fabrication operations may involve various deposition processes to deposit various films to form integrated circuits and related devices by various methods including physical vapor deposition (PVD), chemical vapor deposition (CVD), plasma enhanced chemical vapor deposition (PECVD), atomic layer deposition (ALD), or plasma enhanced atomic layer deposition (PEALD). A consequence of the deposition process is that the various materials are not only deposited on a substrate where the various materials are to be deposited, but also on the surfaces of components in the process chamber or on the interior surfaces of the process chamber in which deposition processes occur. One or more components in the process chamber may include a showerhead, or a pedestal. The process chamber may also include a component that may act as both a showerhead and a pedestal (or hereinafter referred to as a “showerhead-pedestal”) in the interior of the process chamber. A showerhead-pedestal may be a pedestal that may be involved in a backside deposition. Backside deposition may be defined as forming one or more layers on the backside of a substrate that is opposite to the substrate's front side where at least a portion of an electronic device are typically formed. For many applications, a backside layer may be deposited to compensate for wafer (i.e., substrate) bow which may occur due to a number of factors, such as but not limited to deposition of thick films or high stress films on the front side of the substrate. A backside layer may be formed from any one of many possible materials including but not limited to an amorphous silicon layer. During backside deposition, a substrate may be positioned in a process chamber having both a showerhead and a bottom showerhead (which may be a showerhead-pedestal), with a substrate holder to hold and support the substrate between the top showerhead and a bottom showerhead.

A gaseous precursor or other reactant gas may be provided from a precursor source or a source gas supply through a plurality of passages formed through the showerhead-pedestal Consequently, during deposition, deposits from the various materials are formed on the interior surfaces of the process chamber, including interior walls of the process chamber or the surfaces of one or more components (i.e., parts) in the process chamber, and the deposited materials may accumulate over time, forming a film or causing flaking of particles from the deposited materials. Additionally, the deposited material may dissolve, detach, thermally desorb, or evaporate through subsequent processes in the process chamber, which can cause contamination onto a substrate or features formed on a substrate being processed in the process chamber. For example, the deposited material may flake from the surfaces of the components as particles, and land on a substrate during processing of the substrate. This contamination is one reason for low production yield or low throughput, because the chamber may need to be frequently maintained or cleaned to prevent contamination; additionally or alternatively, contamination may also potentially cause device reliability issues in the devices formed on the substrate. Accumulated materials are periodically removed to avoid contamination of the process chamber.

One way of removing contaminants (e.g., wall deposits) deposited on surfaces in the process chamber may be introducing a plasma including fluorine (F) species. A plasma may include one or more species generated by igniting a gas, and may be referred to as plasma-activated species or plasma species. The term “plasma” may refer to the one or more plasma-activated species or plasma species or any other species formed in the plasma. For example, radicals may be one or more species generated in a plasma, and may be referred to as plasma-activated species. The radicals may be referred to as atom radical or radical species. For example, hydrogen radicals may also be referred to as hydrogen atom radicals or hydrogen radical species. In some embodiments, all, or substantially all, or a substantial fraction of the hydrogen atom radicals can be in the ground state, e.g., at least about 90% or about 95% of the hydrogen atom radicals adjacent the substrate may be in the ground state.

In some embodiments, the plasma may include radicals, positive ions, electrons, charged neutrals, other plasma species, or combinations thereof. In some embodiments, fluorine-containing species include fluorine-containing source gases including fluorine atoms, fluorine-containing plasma (e.g., radicals, positive ions, electrons, charged neutrals, and other plasma species), or combinations thereof. In one example, fluorine-containing species may include fluorine-containing source gases, fluorine-containing radicals, positive ions, electrons, charged neutrals, a plasma thereof, or combinations thereof. For example, fluorine-containing species may include a plasma of one or more fluorine-containing source gases, e.g., nitrogen trifluoride (NF₃) plasma.

For this type of cleaning, one or more source gases (e.g., cleaning gases) including nitrogen trifluoride (NF₃), molecular fluorine (F₂), carbon tetrafluoride (CF₄), carbon hexafluoride (C₂F₆), xenon difluoride (XeF₂), fluoromethane (CH₃F), difluoromethane (CH₂F₂), tetrafluoroethylene (C₂F₄), hexafluoroethane (C₂F₆), octafluoropropane (C₃F₈), sulfur hexafluoride (SF₆), and combinations thereof, and other fluorine-containing compounds (i.e., fluorine-containing reactants), may be supplied to a plasma source. The plasma source may be an inductively coupled plasma reactor, a capacitively coupled plasma reactor, a microwave plasma reactor, a DC plasma reactor, or a laser-created plasma reactor. The plasma generated from the plasma source may include one or more radicals, and flow into the process chamber to remove accumulated materials deposited on the interior surfaces of the process chamber. For example, fluorine-containing species (e.g., NF₃ plasma) may react with silicon (Si) in silicon-containing deposits on the interior surfaces of the process chamber or on the surfaces of one or more components, generating silicon tetrafluoride (SiF₄) that is volatile.

A process chamber may include interior surfaces of the process chamber or one or more components (e.g., a pedestal, a showerhead, or a showerhead-pedestal) that are made of a metal such as aluminum, aluminum alloy, or aluminum-containing material. Fluorine-containing species may react with silicon (Si) in the silicon-containing deposits to remove the silicon-containing deposits from the interior surfaces of the process chamber. Fluorine-containing species may also react with aluminum in the aluminum-containing component to form aluminum fluoride (AlFx) (e.g., aluminum trifluoride, AlF₃) or aluminum oxyfluoride (AlOxFy), The introduction of the fluorine-containing species (e.g., NF₃ plasma) into the process chamber may generate AlFx or AlOxFy-containing layers or particles on the surfaces including aluminum, e.g., interior walls of the process chamber or the surfaces of the aluminum-containing components. After periodic cleaning of the inner chamber surfaces using fluorine-containing species, AlFx or AlOxFy may also be cleaned from the interior surfaces to avoid further contamination of a substrate in a subsequent semiconductor fabrication process.

### PROCESS FLOW

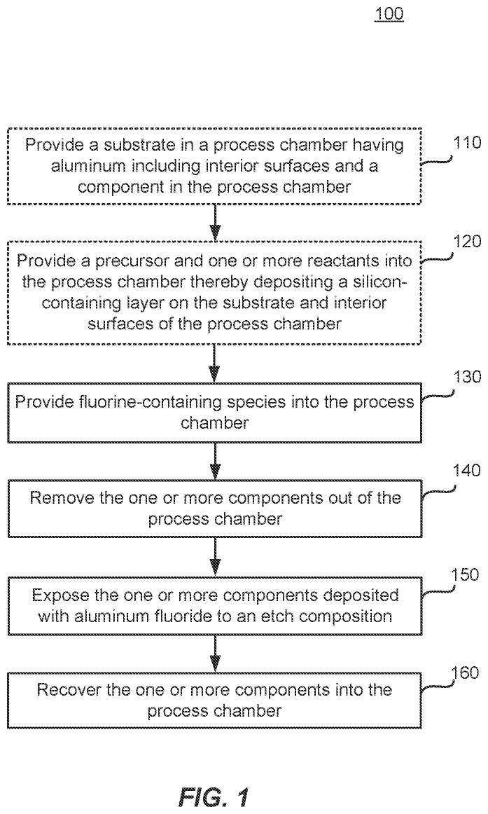

FIG. 1 illustrates a flow chart 100 of an example method of cleaning surfaces of one or more components in a process chamber according to some embodiments. In optional operation 110, a substrate may be provided in the process chamber having interior surfaces, and defining a space in which a substrate is positioned for processing, e.g., deposition or etching. For example, a substrate may be transferred to the interior of the process chamber by a substrate transfer module (e.g., a robot arm unit) for providing a clean, pressurized environment to minimize risk of contamination of substrates being processed as they are moved from the exterior of the process chamber to the interior of the process chamber. In some embodiments, the substrate may include one or more features formed on the substrate. For example, the one or more features may be one or more partially fabricated integrated circuits. In some embodiments, the substrate without any features may be provided. Prior to optional operation 110, a substrate may be cleaned to remove any undesirable layer deposited on the substrate. The process chamber may also include one or more components provided in the interior of the process chamber. The components may include a pedestal, a showerhead, or a showerhead-pedestal, and may be mechanically coupled with other parts in the process chamber. In some embodiments, the interior surfaces of the process chamber, or the surfaces of one or more components (such as any one or more of the pedestal, showerhead, or showerhead-pedestal, among others) may include aluminum, aluminum alloy, or aluminum-containing material.

In optional operation 120, a precursor and a reactant may be provided into the process chamber for depositing a layer on the substrate. The precursor may be a silicon-containing precursor described herein, and may be deposited in the one or more features on a substrate to form a silicon-containing layer, e.g., silicon oxide, silicon nitride, doped or undoped amorphous silicon, doped or undoped silicon carbide, or combinations thereof. A silicon-containing layer may be formed on the front or frontside of the substrate, or a silicon-containing layer may be formed on the backside of the substrate. The “front” of the substrate may refer to the surface of the substrate where a semiconductor device may be partially fabricated. In some embodiments, the “front” of the substrate is upward facing or facing a showerhead positioned over the substrate. In some embodiments, the silicon-containing layer is formed on the backside of the substrate. For example, one or more silicon-containing layers may be formed on the backside of the substrate to counteract the bending of deposited multiple layers on the frontside of the substrate. Operation 120 may also involve the deposition of another silicon-containing layer with different chemical composition on top of the silicon-containing layer formed in operation 120. A silicon-containing layer may be deposited by any suitable deposition process such as PVD, CVD, PECVD, ALD, or PEALD.

For some embodiments, deposition of the silicon-containing layer can occur by flowing one or more silicon-containing precursors into the process chamber housing the substrate. The silicon-containing precursors are delivered to a region over a surface of the substrate where they are adsorbed onto the surface of the substrate and may be thermally decomposed or chemically adsorbed onto sites on the surface of the substrate to form a highly conformal silicon-containing layer. In some embodiments, forming a silicon-containing layer by CVD may involve controlling the deposition pressure ranging about 0.1 to about 40 Torr, or about 0.5 to about 20 Torr. Substrate temperature during the deposition may be controlled to be about 300 to about 700 °C, or about 400 to about 650 °C. After deposition, a step coverage for the silicon-containing layer may be at least about 85%. In some embodiments, a step coverage may be at least about 90% or at least about 95%.

Without being limited by any theory, silicon-containing precursors having low sticking coefficients may be capable of producing highly conformal silicon layer. “Sticking coefficient” is a term used to describe the ratio of the number of adsorbate species (e.g., fragments or molecules) that adsorb/stick to a surface compared to the total number of species that impinge upon that surface during the same period of time. The symbol Se is sometimes used to refer to the sticking coefficient. The value of S_{c} is between 0 (meaning that none of the species stick) and 1 (meaning, that all of the impinging species stick). Various factors affect the sticking coefficient, including the type of impinging species, surface temperature, surface coverage, structural details of the surface, and the kinetic energy of the impinging species. Certain species are inherently more “sticky” than others, making them more likely to adsorb onto a surface each time the species impinges on the surface. These stickier species have greater sticking coefficients (all other factors being equal). In some cases, the sticking coefficient of the precursors (at the relevant deposition conditions) may be about 0.05 or less, for example about 0.001 or less.

While thermal deposition or thermal decomposition may be used to deposit a silicon-containing film, plasma-based deposition may be used in addition to or as an alternative to thermal deposition or decomposition. In one example, radicals may be generated in a plasma source and introduced into the process chamber during deposition. In some embodiments, a source gas such as a hydrogen-containing gas is introduced to a plasma source and the plasma ignites the hydrogen-containing gas which may form excited hydrogen radicals. In some implementations, when the excited hydrogen radicals lose their energy, or relax, the excited hydrogen radical may become a substantially low energy state hydrogen radical or a ground state hydrogen radical. Hydrogen radicals in a substantially low energy state or ground state can be capable of breaking Si—H and/or Si—Si bonds while generally preserving Si—O, Si—N, and/or Si—C bonds. In some implementations, process conditions may be provided so that excited hydrogen radicals lose energy or relax to form substantially low energy state or ground state hydrogen radicals.

The silicon-containing precursors and the source gas for the hydrogen radicals may be delivered with other species, including carrier gas. Example carrier gases include but are not limited to argon (Ar), helium (He), neon (Ne), krypton (Kr), and xenon (Xe). The concentration of the carrier gas can be substantially greater than the concentration of the source gas. As used herein, “substantially greater” with respect to the concentration of carrier gas relative to source gas can refer to a percentage by volume that is at least three times greater. By way of an example, hydrogen gas may be provided in a helium carrier gas at a concentration of about I to about 50% hydrogen. The presence of the carrier gas can contribute to increased ionization of the source gas and reduced recombination. Though lower pressure typically facilitates increased ionization of the source gas and reduced recombination, the presence of the carrier gas can serve the same effect. Even at a higher pressure, a substantial fraction of radicals may be generated with minimal recombination when a carrier gas such as helium is flowed with the source gas. Higher pressure in the process chamber during deposition may improve the conformality of a silicon-containing layer. Higher pressure in the process chamber may correspond to a pressure range of about 1 to about 10 Torr, or about 1 to about 5 Torr. The substrate temperature during a silicon-containing layer deposition may be controlled to be about 100 to about 400 °C, or about 200 to about 300 °C.

In some embodiments, the silicon-containing precursor may be delivered to a processing region over a surface of the substrate. In some embodiments, depending on the parameters for depositing a silicon-containing layer, the silicon-containing precursor may also be delivered to other locations on the interior surfaces of the process chamber and surfaces of the components other than the substrate on which a silicon-containing precursor is supposed to be deposited. For example, a silicon-containing precursor may deposit on the interior surfaces of the process chamber, on the surfaces of a pedestal, a showerhead, or a showerhead-pedestal and may thus form a silicon-containing layer. Depending on the operations in the process chamber, the silicon-containing material deposited on the interior surfaces of the process chamber or surfaces of the components may have compositions including silicon, carbon, nitrogen, oxygen, or combinations thereof. The silicon-containing material may be formed as a layer or tiny particles. As the number of the substrates processed (e.g., deposition or etching) in the process chamber or the duration of the operation (e.g., deposition or etching) increases, the thickness of the silicon-containing material formed on the interior surfaces increases which can cause flaking and particle defects, and thus may become a contamination source for a substrate in the subsequent operation. For example, the silicon-containing material may sublime and be re-delivered to another location in the chamber, and/or may be re-deposited in the features on the substrate. In another example, silicon-containing particles or flakes may fall to the ground of the process chamber. The interior surfaces of the process chamber, including interior walls of the process chamber or the surfaces of one or more components (i.e., parts) in the process chamber, may be periodically cleaned to remove silicon-containing materials from the interior surfaces of the process chamber after a certain number of the substrates are processed or after the duration of the operations exceeds a certain time period.

In some embodiments, after the interior surfaces of the process chamber are deposited with the silicon-containing layers, one or more substrates in the process chamber may be removed out of the process chamber. For example, the substrate may be transferred by a substrate transfer module (e.g., a robot arm unit) to the exterior of the process chamber. In operation 130, a fluorine-containing species may be supplied into the interior of the process chamber for a certain duration for chamber cleaning, that is, cleaning the silicon-containing layer deposited on the interior surfaces of the process chamber including interior walls of the process chamber or the surfaces of one or more components (i.e., parts) in the process chamber. As described, fluorine-containing species may include fluorine-containing source gases, fluorine-containing plasma (e.g., radicals, ions, charged neutrals, and other plasma species), or combinations thereof. In one example, the fluorine-containing species, e.g., nitrogen trifluoride (NF₃) plasma, may react with silicon in the silicon-containing material, thereby generating a silicon tetrafluoride (SiF₄) byproduct that is volatile and may be relatively easily removed from the interior of the process chamber.

In some embodiments, in addition to the reaction between the silicon-containing material and a fluorine-containing species, an aluminum-containing (e.g., aluminum, aluminum alloy, or other aluminum-containing material) component, e.g., a showerhead, a pedestal, a showerhead-pedestal, or interior walls of the chamber, may also be exposed to the fluorine-containing species. In some embodiments, the components may have a surface including aluminum, aluminum alloy, or other aluminum-containing material. The exposure of the aluminum-containing components to the fluorine-containing species may generate AlFx or AlOxFy byproducts on the surface of the components. In one example, the byproducts may include aluminum trifluoride (AIF₃). AIFx including AlF3 or AlOxFy may not be volatile, and may not be easily removed from the surfaces of the components. In some embodiments, a silicon-containing material on the interior surfaces of the process chamber may be cleaned or removed in the form of, for example, silicon tetrafluoride, while AlFx or AlOxFy may still remain as a condensed form, e.g., in the form of a layer or particles on the interior surfaces of the process chamber. AlFs or AlOxFy may be formed on any surface including aluminum, aluminum alloy, or aluminum-containing material in the interior of the process chamber that is exposed to a fluorine-containing species. For example, for a showerhead-pedestal that may be used in the backside deposition, AlFx or AlOxFy may be formed not only on the extemal surfaces of a showerhead-pedestal, but also on the surfaces of a plurality of gas passages (e.g., holes) passing through the showerhead-pedestal. The amount of AlFx or AlOxFy formed on the surfaces of the components may depend on the parameters for cleaning the interior surfaces of the process chamber. For example, supplying a fluorine species (e.g., NF₃ plasma cleaning) for a longer duration may generate an increased amount (e.g., thicker layer, or bigger or aggregated particles) of AlFx or AlOxFy deposited on the interior surfaces of the process chamber.

In some embodiments, the components that are removed in operation 140 may be, when being used in the process chamber, mechanically and/or fluidly coupled to the process chamber or other parts in the process chamber. For example, the components may include a pedestal, a showerhead, or a showerhead-pedestal.

In operation 140, the components having layers or particles including AlFx or AlOxFy deposited on the surfaces may be removed from the process chamber for cleaning AlFx or AlOxFy from the surfaces. Prior to operation 140, the operation of the process chamber may be interrupted or stopped. For example, an apparatus including the process chamber may not be operational or may be shut down prior to operation 140. A vacuum pump fluidly coupled with the process chamber may be configured to be not operational, and the process chamber may not be under low chamber pressure. In one example, the process chamber may be at atmospheric pressure.

The components may be disassembled or detached from the process chamber, and transferred out of the process chamber during operation 140. For example, the components may be removed using a transfer arm from the process chamber.

Alternatively, in some embodiments, the components having surfaces deposited AlFx or AlOxFy layers or particles may not be removed from the process chamber. Instead, etch operation according to some embodiments may be performed in the interior of the process chamber without moving the components out of the process chamber.

In operation 150, the components having AlFx or AlOxFy formed thereon may be exposed to one or more etch compositions for a certain time period, thereby removing the AlFx or AlOxFy from surfaces of the components. In some embodiments, the etch compositions may include a hydroxyl group-containing composition such as a hydroxyl group-containing gas or plasma. The hydroxyl group-containing composition may include a hydroxyl group-containing alkali composition, and may include potassium hydroxide (KOH), sodium hydroxide (NaOH), ammonium hydroxide (NH₄OH), tetramethylammonium hydroxide (TMAH, C₄H₁₃NO), tetraethylammonium hydroxide (TEAH, C₈H₂₁NO), or combinations thereof. In some embodiments, the etch compositions (e.g., hydroxyl group-containing composition) may be mixed with water or deionized water to form an etch composition solution. The etch composition solution may include a hydroxyl group-containing solution having a certain concentration. In some embodiments, the concentration of the etch composition solution, which may include potassium hydroxide (KOH), sodium hydroxide (NaOH), ammonium hydroxide (NH4OH), tetramethylammonium hydroxide (TMAH, C₄H₁₃NO), tetraethylammonium hydroxide (TEAH, C₈H₂₁NO), or combinations thereof as described herein, may be about 0.1 to about 45 percent weight/volume [% (W/V)], about 0.5 to about 30 % (W/V), about 1 to about 20 % (W/V), about 1.5 to about 10 % (W/V), or about 2 to about 7 % (W/V). In some embodiments, the etch composition solution may contact the AlFx or AlOxFy formed on the components for about 0.1 to about 45 minutes, about 1 to about 30 minutes, about 1 to about 10 minutes, about 5 to about 25 minutes, about 8 to about 20 minutes, about 10 to about 20 minutes, or about 10 to about 15 minutes. The duration may depend on the thickness of the AlFx or AlOxFy or the condition of the surface (e.g., surface roughness etc) on which AlFx or AlOxFy is formed or other process conditions during operation 150.

It is to be understood that any etch composition described herein and the exposure time of AlFx or AlOxFy to the etch composition may be combined to remove AlFx or AlOxFy from the surfaces of the component according to some embodiments. For example, AlFx (e.g., AlF₃) or AlOxFy may be exposed to a potassium hydroxide solution having a concentration of about 1 to about 20 % (W/V) for about 1 to about 30 minutes, about 1 to about 10 minutes, about 5 to about 25 minutes, about 8 to about 20 minutes, or about 10 to about 15 minutes. In another example, AlFx (e.g., AlF₃) or AlOxFy on a component may be exposed to a potassium hydroxide solution having a concentration of about 3 to about 10 % (W/V) for about 5 to about 25 minutes. In yet another example, a sodium hydroxide solution with about 1.5 to about 10 % (W/V) may be used in removing AlFx or AlOxFy by soaking for about 8 to about 20 minutes, or about 10 to about 15 minutes. In some embodiments, the temperature of the etch compositions solution during AlFx etch may be ambient temperature. In some embodiments, the temperature may be set at or may be adjusted from about 0 to about 100 °C, or from about 10 to about 90 °C. In some embodiments, ultrasonic frequency (e.g. greater than 20 KHz) may be applied to the component during at least a portion of the treatment time period to increase the efficiency of the etch operation.

After exposure of the AlFx or AlOxFy coated component to an etch composition solution (e.g., hydroxyl group-containing composition mixed with water) with a certain concentration for a certain duration, the component may be removed from the etch composition solution. Subsequently the component may be rinsed using high purity deionized water to remove any etch composition (e.g., hydroxyl group-containing composition) remaining on the surface of the component. After rinsing, the component may be baked at about 200 °C, from about 80 to about 140 °C, or from about 100 to about 110 °C for any suitable duration, such as about 0.1 to about 8 hours, about 1 to about 6 hours, or about 3 to about 5 hours to remove any remaining moisture from the surface of the component. After exposure to the solution, the rinsing, and the baking, the component may be substantially free of AlFx or AlOxFy. In one embodiments, component may be considered to be substantially free of AlFx or AlOxFy when the number of AlFx or AlOxFy in the form of particle or other condensed forms is less than the number of AlFx or AlOxFy on a new replacement component.

In operation 160, the component that is substantially free of AlFx may be considered to be “recovered” such that it can be reused again in the process chamber. This is distinct from using a new replacement component part. Here, for example, the components may be transferred to the interior of the process chamber for reinstallation for subsequent operations such as deposition, or etch. In some embodiments, the component or a package including the one or more components may be re-assembled to the process chamber or another components in the process chamber. Subsequently, the process chamber may be operated to reach a vacuum level (i.e., vacuum level) that is suitable for a subsequent operation, e.g., depositing a layer or etching a layer, In some embodiments, a substrate may be transferred into the process chamber prior to or after reaching the desired pressure range for an operation such as a deposition, and a chemical precursor for depositing a silicon-containing layer and a reactant may be provided for depositing a layer. In another example, a substrate may be transferred into the process chamber for etching at least a portion of the features on the substrate.

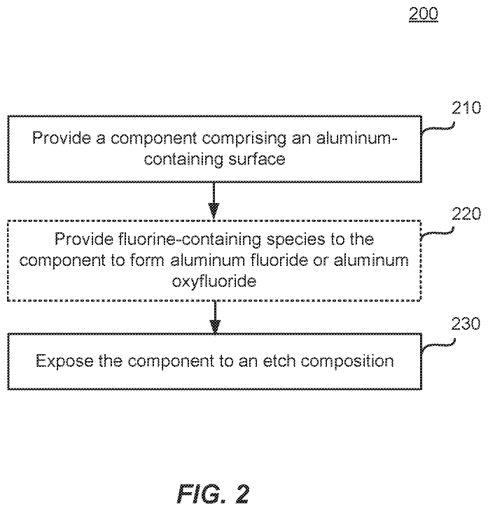

FIG. 2 illustrates a flow chart 200 of an example method of cleaning the surface of a component according to some embodiments. In operation 210, a component having an aluminum-containing surface may be provided. In some embodiments, the surface may include aluminum, aluminum alloy, or other aluminum-containing material. In some embodiments, the surface may include aluminum, aluminum alloy, aluminum fluoride (e.g., aluminum trifluoride), aluminum oxyfluoride, or combinations thereof. The component may include a showerhead, a pedestal, a showerhead-pedestal, or any other components or parts associated with the operation of a process chamber.

In optional operation 220, a fluorine-containing species may be provided to the surface of the component, thereby forming AlFx or AlOxFy on the aluminum-containing surface. The fluorine-containing species may include a plasma including fluorine species as described herein. For example, a fluorine-containing species may include a plasma of one or more fluorine-containing gases, e.g., nitrogen trifluoride (NF₃) plasma.

In operation 230, the component may be exposed to an etch composition solution. In some embodiments, the component may be soaked in the etch composition solution for etching any aluminum fluoride or aluminum oxyfluoride that may be present on the surface of the component. The etch composition solution may include potassium hydroxide, sodium hydroxide, ammonium hydroxide, tetramethylammonium hydroxide, tetraethylammonium hydroxide, or combinations thereof. In some embodiments, the concentration of the etch composition solutions may be about 0.1 to about 45 percent weight/volume [% (W/V)], about 0.5 to about 30 % (W/V), about 1 to about 20 % (W/V), about 1.5 to about 10 % (W/V), or about 2 to about 7 % (W/V). In addition to soaking, an etch composition solution may also be provided to the surface of the component via gas phase by atomizing an etch composition solution at an elevated temperature such as about 10 °C to about 90 °C.

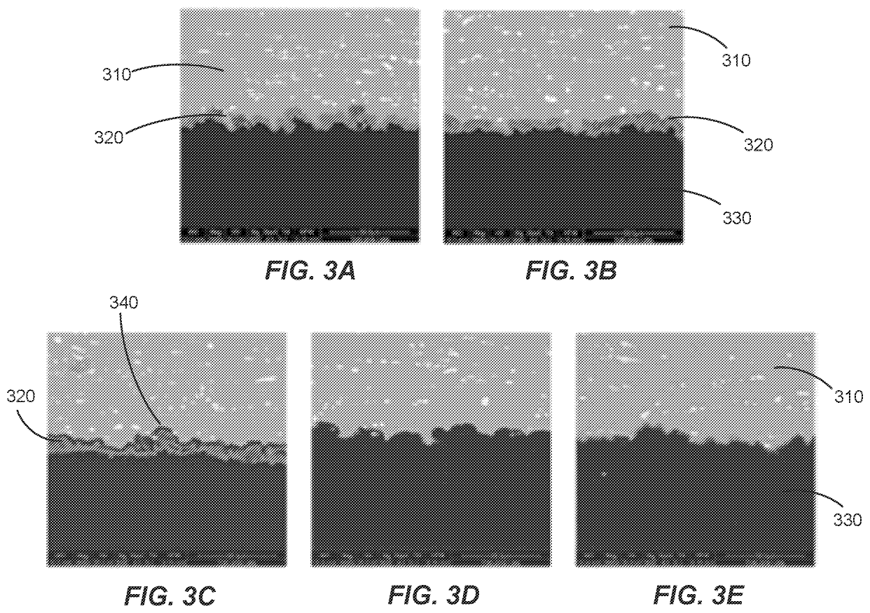

FIGS. 3A-3E are scanning electron micrograph (SEM) images showing the progress of AlFx etching from the surfaces of a component with etch time according to some embodiments. FIGS. 3A-3E show the cross-sectional areas for an aluminum-containing component (e.g., showerhead-pedestal) 310. A black area 330 in the lower portion of the images in FIGS. 3A-3F corresponds to carbon for preparing SEM samples. The component having the surface coated with AlFx layer 320 was soaked in a potassium hydroxide (KOH) solution with a concentration of 1.5 to 10 % (W/V) for various soaking time. The presence of AlFx layer 320 was confirmed by performing a chemical elemental analysis using an energy dispersive spectroscopy (EDS, Hitachi, Japan). Both quantitative and qualitative analysis showed that the layer 320 includes AlFx including AlF₃. FIG. 3A is the image taken prior to soaking the sample in the KOH solution (soak time=0 minutes), and FIGS. 3B-3E are the images taken with a 2 minute increments after the soaking started. That is, FIG. 3B is the image taken for the sample after 2 minutes of soaking, FIG. 3C is taken for the sample after 4 minutes of soaking, FIG. 3D is taken for the sample after 6 minutes of soaking, and FIG. 3E is taken for the sample after 8 minutes of soaking.

FIG. 3A shows that about 4 to about 10 micron thick AlFx layer 320 is present on the component surface prior to the etch operation. FIG. 3B shows that no noticeable change in the AlFx 320 was observed after soaking the component in the KOH solution up to for about 2 minutes. FIG. 3C shows that a gap 340 (e.g., darker lines) is formed along the boundary between component 310 and AlFx 320 after about 4 minutes of soaking in the KOH solution. In some embodiments, during the soak, the KOH solution may have loosened or dissolved AlFx. In some embodiments, the KOH solution may also have penetrated the boundary between AlFx 320 and component 310 on which AlFx is formed, and loosened the adhesion between the AlFx and the aluminum-containing surface of the component. FIG. 3D shows that the AlFx layer is removed from the surface of component 310 after about 6 minutes of soaking in the KOH solution. The KOH, having fully penetrated the gap 340 between the component and AlFx, may have further relieved the adhesion of AlFx layer enough to fully separate AlFx layer from the surface of the aluminum-containing component. The absence of adhesion of AlFx to the surface of the component may involve lifting at least a portion of AlFx layer from the surface of the component, which may be similar to a lift-off, where a layer to be removed is detached from the underlying substrate or underlying layer. FIG. 3E shows that no further change is observed after AlFx is removed from the component, and confirms that the lift-off of the AlFx is irreversible.

In some embodiments, any hydroxyl group-containing solution with a certain concentration range as described herein may be used in etching AlFx or AlOxFy from the component surface. The chemical composition and concentration of the hydroxyl group-containing solution may be parameters in etching AlFx or AlOxFy from the surfaces of the component. For example, the concentration of the hydroxyl group-containing solution may be inversely proportional to the time for etching AlFx or AlOxFy. Hydroxyl group-containing solution having lower concentration may extend the time for etching AlFx or AlOxFy from the surface of the component. A higher concentration of hydroxyl group-containing solution may over-etch the component. For example, depending on the duration or a soaking temperature, a hydroxyl group-containing solution having about 60 % (W/V) or above may etch out an aluminum-containing component.

In addition to SEM images taken for each step of etch operation with soak time, the removal of AlFx may be confirmed separately by measuring the surface profile of the components deposited with AlFx with soak time. For example, the showerhead-pedestal samples for FIGS. 3A-3C show the presence of an about 4 to about 10 micron thick layer on the component. For showerhead-pedestal samples for FIGS. 3D-3E, the surface profiling did not indicate the presence of an additional layer on the component. These profiling studies may further confirm the observation that AlFx is substantially removed by the KOH solution as shown in the SEM images sequentially taken with soak time.

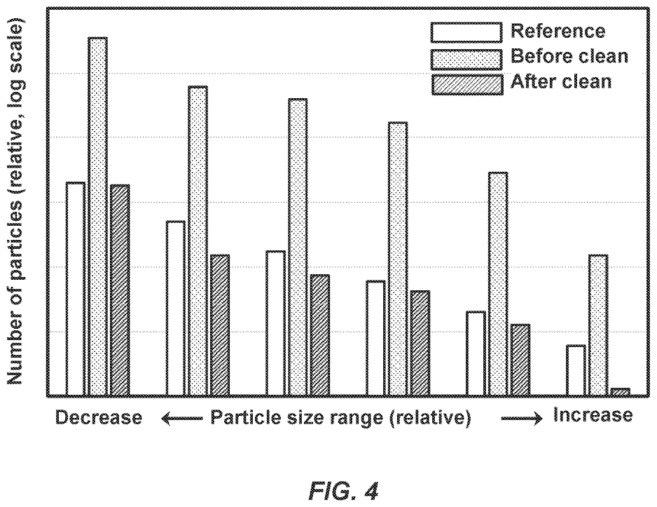

FIG. 4 is a graph illustrating the size range and the number of AlFx particles on a showerhead-pedestal prior to and after cleaning operation according to some embodiments, The horizontal axis of the graph in FIG. 4 shows the range of AlFx particle size in an arbitrary scale. The size range of AlFx particles increases from left to right. The vertical axis of the graph represents the relative number of AlFx particles on the surface of the showerhead-pedestal in a log scale. Each group of bars includes three bars, that is, a reference (empty bar), before clean (dotted bar), and after clean (hatched bar). The height of the bar referred to as “reference” in each group of bars corresponds to the number of AlFx particles on the surface of an as-manufactured showerhead-pedestal, and was used as a reference to compare with the number of AlFx particles measured after chamber cleaning using a fluorine-containing species, and after cleaning operation according to some embodiments. The height of the dotted bar referred to as “before clean” corresponds to the number of AlFx particles on the surface of the showerhead-pedestal after exposure to a fluorine-containing species for cleaning the interior surfaces of a process chamber after a certain duration of deposition operations or after a certain number of substrates are processed (e.g., deposition of etch). The height of the hatched bar referred to as “after clean” corresponds to the number of AlFx particles on the surface of the showerhead-pedestal after soaking the showerhead-pedestal in the etch composition solution (e.g., a hydroxyl group-containing solution) for a certain time period as described herein.

For determining the size range and number of AlFx particles on the showerhead-pedestal at each stage, the showerhead-pedestal with AlFx particles was vibrated at high frequency in a liquid medium to separate AlFx particles from the showerhead-pedestal. Deionized water (with the resistivity up to about 2 million ohm-cm, MOhm-cm) or ultrapure water (with the resistivity up to about 18.2 MOhm-cm) may be used as a liquid medium. The AlFx particles dispersed in the liquid medium were analyzed by a light scattering method to measure the size and number of AlFx particles. FIG. 4 shows that, compared to the as-manufactured showerhead-pedestal, the number of AlFx particles on the showerhead-pedestal increases after the showerhead-pedestal was exposed to the fluorine-containing species during the chamber cleaning using a fluorine-containing species. This increase is due to the AlFx generated from the reaction between aluminum on the surface of the showerhead-pedestal and a fluorine-containing species. After cleaning the showerhead-pedestal using a hydroxyl group-containing solution according to some embodiments, the number of AlFx particles was reduced by more than 99% compared to the particle numbers on the showerhead-pedestal after the chamber cleaning. The reduction of the number of AlFx particles was observed for all size ranges of AlFx particles. In some embodiments, for most of the size ranges measured, the number of AlFx particles after cleaning was comparable to or even less than the number of AlFx particles on the as-manufactured showerhead-pedestal. FIG. 4 shows that the cleaning operations using an etch composition as described herein are effective in removing AlFx particles from an aluminum-containing component that was exposed to fluorine-containing species. Further, this reduction in the number of AlFx particles may permit a showerhead-pedestal to be removed from a process chamber, cleaned according to the embodiments, recovered in the process chamber for additional uses without affecting the substrate contamination during an operation, which may be beneficial in reducing manufacturing cost or operational cost of the process chamber in an apparatus, e.g., deposition apparatus or etch apparatus.

### Apparatus

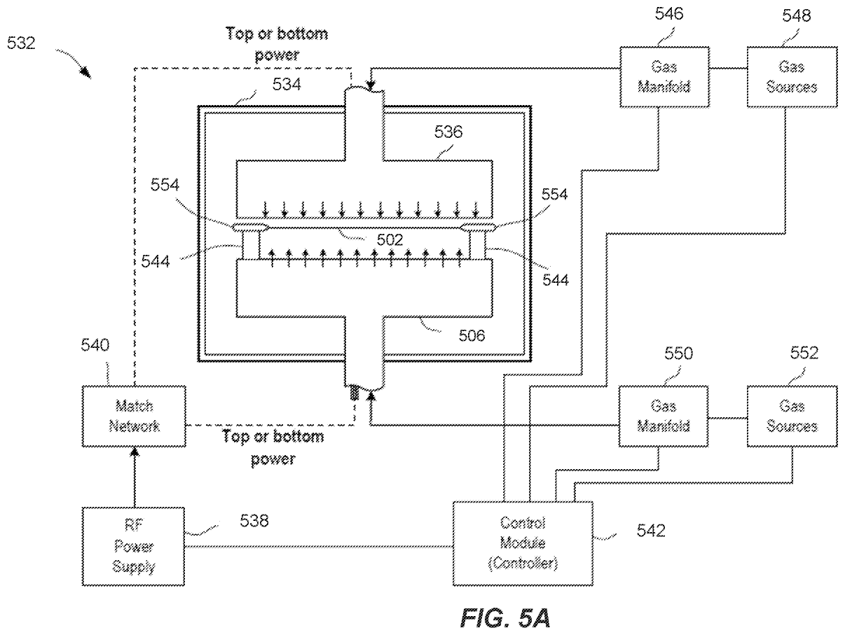

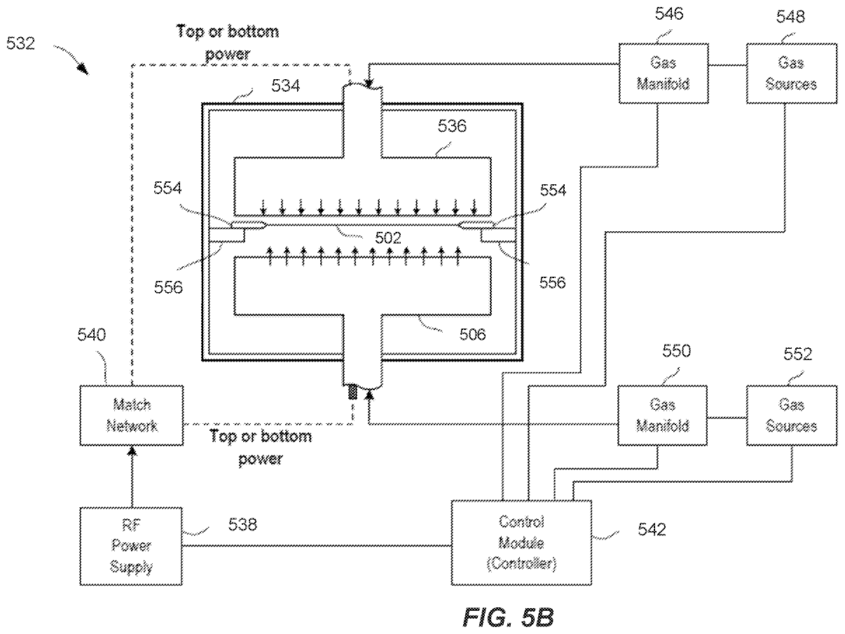

FIG. 5A is a block diagram that illustrates a substrate processing system 532 used to perform processing on a substrate (e.g., wafer) 502 according to some embodiments. As shown, the substrate processing system may include a process chamber 534. A center column may be configured to support a pedestal on which the wafer 502 is being processed, e.g., a film is being formed on the top surface of the substrate 502, or on the backside of the substrate 502. The pedestal, in accordance with some embodiments disclosed herein, may be referred to as a showerhead-pedestal 506. A showerhead 536 may be disposed over the showerhead-pedestal 506.

In some embodiments, the showerhead 536 may be electrically coupled to power supply 538 via a match network 540 for powering a plasma. The power supply 538 may be controlled by a control module 542, e.g., a controller. In some embodiments, power may be provided to the showerhead-pedestal 506 instead of the showerhead 536. The control module 542 may be configured to operate the substrate processing system 532 by executing process input and control for specific process recipes. Depending on whether the top surface of the substrate 502 is receiving a deposited film or the bottom surface of the substrate 502 is receiving a deposited film, the controller module 542 may set various operational inputs for a process recipe, such as power levels, timing parameters, process gasses, mechanical movement of a substrate 502, and/or the height of the substrate 502 relative to the showerhead-pedestal 506.

In some embodiments, the plasma energy may be controlled by controlling one or more of the chamber pressure, a gas concentration, a RF source power, a RF source frequency, and a plasma power pulse timing. For example, RF power supply 538 and matching network 540 may be operated at any suitable power to form a plasma having a desired composition of radical species. Examples of suitable RF power ranges may be about 50-1,000 watts (W), or 100-500 W per station. Likewise, RF power supply 538 may provide RF power of any suitable frequency. In some embodiments, RF power supply 538 may be configured to control high-and low-frequency RF power sources independently of one another. Example low-frequency RF frequencies may include, but are not limited to, frequencies less than 1 MHz, or between 50 kHz and 600 KHz. Example high-frequency RF frequencies may include, but are not limited to, frequencies between 1.8 MHz and 2.45 GHz. In some embodiments, high-frequency of 13.56 MHz or about 27 MHz may be provided. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the center column may also include lift pins, which are controlled by a lift pin control. Such lift pins may be used to raise the substrate 502 from the showerhead-pedestal 506 to allow an end effector (not shown) to pick the substrate and to lower the substrate 502 after being placed by the end effector. The end effector may also place the substrate 502 over spacers 544. As will be described below, the spacers 544 may be sized to provide a controlled separation of the substrate 502 between a top surface of the showerhead 536 (facing the substrate) and a top surface of the showerhead-pedestal 506 (facing the substrate).

In some embodiments, the substrate processing system 532 may further include a first gas supply including a first gas manifold 546 that is connected to first gas sources 548, e.g., gas chemistry supplies from a facility and/or inert gases. For example, the gas chemistry supplies may include one or more silicon-containing precursors described herein and one or more carrier gases. Examples of the carrier gas include, but not limited to helium (He), neon (Ne), argon (Ar), krypton (Kr), xenon (Xe), deuterium (D₂), hydrogen (H₂), and nitrogen (N₂). In another example, one or more fluorine-containing species may be fluidly coupled to the first gas supply including the first gas manifold 546 that is connected to the first gas source 548. Fluorine-containing species include fluorine-containing source gases, fluorine-containing plasma (e.g., radicals, ions, charged neutrals), or mixtures thereof. Fluorine-containing source gas may include nitrogen trifluoride (NF₃), molecular fluorine (F₂), carbon tetrafluoride (CF₄), carbon hexafluoride (C₂F₆), xenon difluoride (XeF₂), fluoromethane (CH₃F), difluoromethane (CH₂F₂), tetrafluoroethylene (C₂F₄), hexafluoroethane (C₂F₆), octafluoropropane (C₂F₈), sulfur hexafluoride (SF₆), fluorine-containing plasma, or mixtures thereof. In some embodiments, the one or more fluorine-containing species may be generated from a plasma source (e.g., a remote plasma source) that may be fluidly coupled to the first gas supply including the first gas manifold 546. Depending on the processing being performed over a top surface of the substrate 502, the control module 542 may controls the delivery of first gas sources 548 via the first gas manifold 546. The chosen gases may then be flown into the showerhead 536 and distributed in a space volume defined between a face of the showerhead 536 that faces that substrate 502 when the substrate is resting over the pedestal and the substrate 502. In some embodiments, the one or more sources of gas and/or liquid may be provided by atomizer as a fine spray without heating to an elevated temperature the one or more sources of gas and/or liquid. In some embodiments, the one or more sources of gas and/or liquid may be further diluted by one or more suitable solvents or liquids designed to be suitable for atomization. The vaporizing may be a direct inject vaporizer, a flow over vaporizer, or both.

In some embodiments, the substrate processing system 532 may further include a second gas supply including a second gas manifold 550 that is connected to second gas sources 552, e.g., gas chemistry supplies from a facility and/or inert gases. For example, the gas chemistry supplies may include one or more silicon-containing precursors described herein and one or more carrier gases. Examples of the carrier gas include, but not limited to helium (He), neon (Ne), argon (Ar), krypton (Kr), xenon (Xe), deuterium (D₂), hydrogen (H₂), and nitrogen (N₂). In another example, one or more fluorine-containing species may be fluidly coupled to the first gas supply including the first gas manifold 546 that is connected to the first gas source 548. Fluorine-containing species include fluorine-containing source gases, fluorine-containing plasma (e.g., radicals, ions, charged neutrals), or mixtures thereof. Fluorine-containing source gas may include nitrogen trifluoride (NF₃), molecular fluorine (F₂), carbon tetrafluoride (CF₄), carbon hexafluoride (C₂F₆), xenon difluoride (XeF₂), fluoromethane (CH₃F), difluoromethane (CH₂F₂), tetrafluoroethylene (C₂F₄), hexafluoroethane (C₂F₆), octafluoropropane (C₃F₈), sulfur hexafluoride (SF₆), fluorine-containing plasma, or mixtures thereof. In some embodiments, the one or more fluorine-containing species may be generated from a plasma source (e.g., a remote plasma source) that may be fluidly coupled to the first gas supply including the first gas manifold 546. Depending on the processing being performed over a bottom surface of the substrate 502, the control module 542 may control the delivery of second gas sources 552 via the second gas manifold 550. The chosen gases may then be flown into the showerhead-pedestal 506 and distributed in a space volume defined between a face of the showerhead-pedestal 506 that faces an backside or under side (e.g., backside) of the substrate 502 and the substrate 502 when the substrate is resting over the spacers 544. The spacers 544 may provide for a separation that optimizes deposition to the backside of the substrate 502, while reducing deposition over the top surface of the substrate 502. In some embodiments, while deposition is targeted for the backside of the substrate 502, an inert gas may be flown over the top surface of the substrate 502 via the showerhead 536, which may push reactant gases away from the top surface and enable reactant gases provided from the showerhead-pedestal 506 to be directed to the backside of the substrate 502.

Further, the gases may be premixed or not. Appropriate valving and mass flow control mechanisms may be employed to ensure that the correct gases are delivered during the deposition and plasma treatment phases of the process. Process gases may exit the chamber 534 via an outlet. A vacuum pump (e.g., a one or two stage mechanical dry pump and/or a turbomolecular pump) may draw process gases out and maintains a suitably low pressure within the reactor by a close loop controlled flow restriction device, such as a throttle valve or a pendulum valve.

In some embodiments, the substrate processing system 532 may further include an atomizer and/or an vaporizer, each of which is fluidly coupled to the interior of the process chamber, and one or more etch composition solution sources. The etch composition solution may include one or more hydroxyl group-containing solution. The one or more hydroxyl group-containing solution may be prediluted to a certain concentration, or mixed with other liquid medium (e.g., deionized water or ultrapure water) before delivered into the process chamber. The atomizer may be provided as a fin spray without heating to an elevated temperature to deliver the etch composition solution into the process chamber for cleaning an interior wall of the process chamber or one or more components in the process chamber. In some embodiments, an etch composition solution with a certain concentration as described herein may be heated by one or more heating element at a certain temperature. The heated etch composition solution may be delivered to the interior of the process chamber by an vaporizer. The vaporizer may be a direct inject vaporizer, a flow over vaporizer, or both.

In some embodiments, a carrier ring 554 may encircle an outer region of the showerhead-pedestal 506. When the top surface of the substrate 502 is being processed, e.g., a material is being deposited thereon, the carrier ring 554 may be configured to sit over a carrier ring support region that is a step down from a substrate support region in the center of the pedestal showerhead-pedestal 506. The top surface of the carrier ring 554 may be generally coplanar with the top surface of the substrate 502. The carrier ring 554 may include an outer edge side of its disk structure, e.g., outer radius, and a substrate edge side of its disk structure, e.g., inner radius, that is closest to where the substrate 502 sits. The substrate edge side of the carrier ring 554 may also include a plurality of contact support structures or “tabs” which may be configured to lift the wafer 502 when the carrier ring 554 is held by the spacers 544. The carrier ring 554 may include a plurality of tabs with a quantity selected from a range to support the substrate 502 during processing. Additional details regarding embodiments of the tabs will follow.

FIG. 5B is a block diagram that illustrates another substrate processing system 532 used to perform processing on the substrate 502, according to some embodiments. In some embodiments, spider forks 556 may be used to lift and maintain the carrier ring 554 in its process height, e.g., to allow depositing in the backside of the substrate 502. The carrier ring 554 may therefore be lifted along with the substrate 502. In some implementations, the carrier ring 554 may be rotated to another station, e.g., in a multi-station system.

Broadly speaking, the embodiments disclosed herein are for a system to deposit PECVD films on the selective side of the substrate (front and/or back) with dynamic control. Some embodiments may include a dual gas-flowing electrode for defining a capacitively-coupled PECVD system. The system may include a gas-flowing showerhead 536 and a showerhead-pedestal 506. In some embodiments, the gas-flowing pedestal (i.e., showerhead-pedestal) is a combination showerhead and pedestal, which enables deposition on a backside of the substrate. The electrode geometry combines features of a showerhead, e.g., a gas mixing plenum, holes, hole-pattern, gas jet preventing baffle, and features of a pedestal. Examples of features of a pedestal include an embedded controlled heater, substrate-lift mechanisms, ability to hold plasma suppression rings, and movability. This enables the transfer of substrates and the processing of gasses with or without RF power from the pedestal.

In some embodiments, the system may have a substrate lift mechanism that tightly controls parallelism of the substrates against the electrodes. In one example, this may be achieved by setting up the lift mechanism parallel to the two electrodes and controlling manufacturing tolerances, e.g., spindle or lift pins mechanisms. In another example, the lift may be achieved by raising the substrate lift parts. This option may not allow dynamic control of the side that gets deposited.

In some configurations, the lift mechanism may allow dynamically controlling the substrate position during processing (before plasma, during plasma, after plasma) to control the side of the deposition, profile of the deposition, and properties of deposited film. The system may further allow selective enabling/disabling of the side where reactants are flown. One side can flow the reactant and the other side can flow inert gases to suppress the deposition and plasma.

In some embodiments, the gap between the side of the substrate that does not need plasma/dep may be tightly controlled. This distance may be controlled to suppress plasma. By not controlling the distance, the substrate may be susceptible to plasma damage. For example, the system may allow a minimal gap from about 2 mm to about 0.5 mm, and in another embodiment from about 1 mm to about 0.05 (limited by the substrate bow), and such gap can be controlled. The gap may be controlled depending on process conditions.

In some embodiments, the gas-flowing pedestal (i.e., showerhead-pedestal) may enable, without limitation: (a) thermal stabilization of the substrate to processing temperature prior to processing; (b) selective design of hole patterns on the showerhead-pedestal to selectively deposit film in different areas of the back-side of the substrate; (c) swappable rings can be attached to achieve appropriate plasma confinement and hole pattern; (d) stable substrate transfer mechanisms within chamber and for transferring substrate outside to another chamber or cassette-such as lift pins, RF-coupling features, minimum-contact arrays; (e) implement gas mixing features, e.g., such as inner plenum, baffle and manifold lines openings; and (f) add compartments in the gas-flowing pedestal (i.e., showerhead-pedestal) to enable selective gas flow to different regions of the backside of the substrate and control flow rates via flow controllers and/or multiple plenums.

In another embodiment, dynamic gap control using substrate lift mechanism enables: (a) control of the distance from deposition or reactant flowing electrode to the side of the substrate that needs deposition or in the middle so that both sides can be deposited; and (b) the lift mechanism to control the distance dynamically during the process (before plasma, during plasma, after plasma) to control the side of the deposition, profile of the deposition, and deposition film properties. In another embodiment, for a deposition mode used to deposit on the backside of the substrate, film edge exclusion control is highly desirable to avoid lithography-related overlay problems. The lift mechanism used in this system is done via a carrier ring 554 that has a design feature to shadow the deposition on the edge. This specifies the edge exclusion control via the design and shape of the carrier ring.

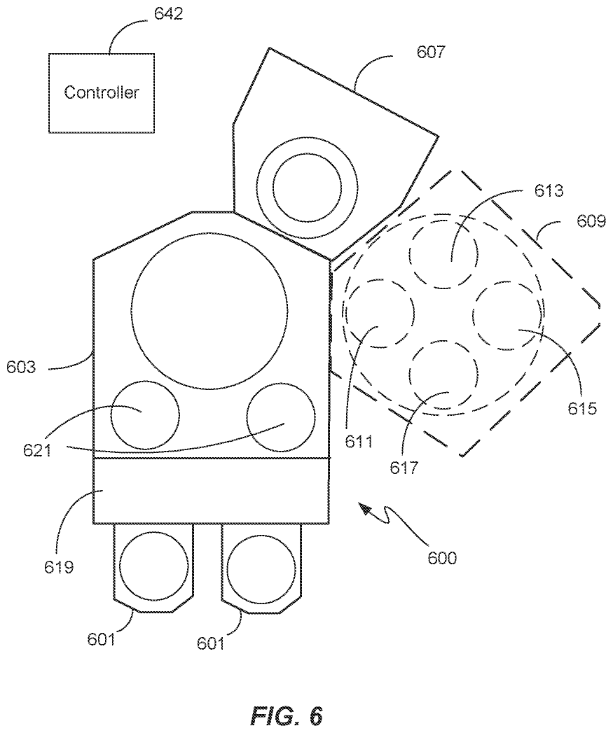

FIG. 6 is a schematic of a process system suitable for conducting deposition processes in accordance with embodiments. The system 600 includes a transfer module 603. The transfer module 603 provides a clean, pressurized environment to minimize risk of contamination of substrates being processed as they are moved between various reactor modules. Mounted on the transfer module 603 is a multi-station reactor 609 capable of performing ALD, treatment, and CVD according to various embodiments. Multi-station reactor 609 may include multiple stations 611, 613, 615, and 617 that may sequentially perform operations in accordance with disclosed embodiments. Each of the multiple stations 611, 613, 615, and 617 may include a process chamber. For example, multi-station reactor 609 may be configured such that station 611 performs a backside deposition of poly-Si sublayer by PECVD or PEALD, station 613 performs a backside deposition of a-Si sublayer by PECVD or PEALD, station 615 performs a first front side deposition of Si-based film by PECVD or PEALD, and station 617 may perform a second front side deposition of Si-based film by PECVD or PEALD. Stations may include a heated pedestal or substrate support, one or more gas inlets or showerhead or dispersion plate.

Returning to FIG. 6, also mounted on the transfer module 603 may be one or more single or multi-station modules 607 capable of performing plasma or chemical (non-plasma) pre-cleans, other deposition operations, or etch operations. The module may also be used for various treatments to, for example, prepare a substrate for a deposition process. The system 600 may also include one or more substrate source modules 601, where substrates are stored before and after processing. An atmospheric robot (not shown) in the atmospheric transfer chamber 619 may first remove substrates from the source modules 601 to loadlocks 621. A substrate transfer device (generally a robot arm unit) in the transfer module 603 may move the substrates from loadlocks 621 to and among the modules mounted on the transfer module 603. The loadlocks 621 may include a remote plasma source. Where the loadlock 621 includes a remote plasma source, the substrate may be exposed to a remote plasma treatment to treat the substrate surface in the loadlock prior to being introduced into a processing chamber. A remote plasma generated from a remote plasma source may be supplied to each process station (described below) for cleaning the interior surfaces according to methods described here. In some embodiments, the remote plasma source may be fluidly coupled to a first process gas supply (not shown here) to receive a process gas from the first process gas supply to generate a plasma, and to provide the plasma generated into the process chamber. In other embodiments, a direct plasma may be generated in the process chamber.

In various embodiments, a system controller 642 is employed to control process conditions during deposition. The system controller 642 will typically include one or more memory devices and one or more processors. A processor may include a CPU or computer, analog and/or digital input/output connections, stepper motor controller boards, etc.

The system controller 642 may control all the activities of the deposition apparatus. The system controller 642 executes system control software, including sets of instructions for controlling the timing, mixture of gases, chamber pressure, chamber temperature, substrate temperature, radio frequency (RF) power levels, substrate chuck or pedestal position, and other parameters of a particular process. Other computer programs stored on memory devices associated with the system controller 642 may be employed in some embodiments. For example, the system controller 642 may be designed such a-Si sublayer and poly-Si sublayer are alternately deposited by changing process parameters, e.g., the flow rates and durations for silicon-containing precursor, and carrier gas; chamber temperature, substrate temperature, chamber pressure, RF frequencies, and RF powers for a-Si deposition and poly-Si deposition.

Typically there will be a user interface associated with the system controller 642. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 642. The signals for controlling the process are output on the analog and digital output connections of the system 600.

The system software may be designed or configured in many different ways, For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code. For example, the system software may be designed such that a program or sections of a program includes performing alternating depositions of a-Si sublayer and poly-Si sublayer by changing the flow rates and durations for silicon-containing precursor, and carrier gas; temperature; chamber pressure; RF frequencies; and RF powers for a-Si deposition and poly-Si deposition.

In some implementations, a system controller 642 is part of a system, which may be part of the above-described examples. Such systems can include semiconductor processing equipment, including a processing tool or tools, chamber or chambers, a platform or platforms for processing, and/or specific processing components (a substrate pedestal, a gas flow system, etc.). These systems may be integrated with electronics for controlling their operation before, during, and after processing of a semiconductor substrate or substrate. The electronics may be referred to as the “controller,” which may control various components or subparts of the system or systems. The system controller 642, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, substrate transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor substrate or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a substrate.

The system controller 642, in some implementations, may be a part of or coupled to a computer that is integrated with, coupled to the system, otherwise networked to the system, or a combination thereof. For example, the system controller 642 may be in the “cloud” or all or a part of a fab host computer system, which can allow for remote access of the substrate processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor substrates.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of substrates to and from tool locations and/or load ports in a semiconductor manufacturing factory.

The system controller 642 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the substrate chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographie patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a substrate stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

### Conclusion

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of cleaning aluminum fluoride or aluminum oxyfluoride, the method comprising:
providing a fluorine-containing species into a process chamber in which one or more components are located;
removing the one or more components out of the process chamber; and
cleaning the one or more components with an etch composition,
wherein the one or more components comprise aluminum, aluminum alloy, or aluminum-containing material.

2. The method of claim 1, wherein cleaning the one or more components comprises etching the aluminum fluoride or aluminum oxyfluoride from a surface of the one or more components.

3. The method of claim 1, wherein cleaning the one or more components comprises separating the aluminum fluoride or aluminum oxyfluoride from a surface of the one or more components.

4. The method of claim 1, wherein the one or more components comprises a pedestal, a showerhead, or a showerhead-pedestal.

5. The method of claim 1, wherein the etch composition comprises a hydroxyl group-containing solution comprising potassium hydroxide, sodium hydroxide, ammonium hydroxide, tetramethylammonium hydroxide, tetraethylammonium hydroxide, or combinations thereof.

6. The method of claim 5, wherein a concentration of the hydroxyl group-containing solution is about 0.1 to about 45 percent weight/volume.

7. The method of claim 6, wherein the concentration of the hydroxyl group-containing solution is about 2 to about 7 percent weight/volume.

8. The method of claim 1, wherein the one or more components are cleaned for about 0.1 to about 45 minutes.

9. The method of claim 1, wherein the fluorine-containing species comprises nitrogen fluoride plasma.

10. The method of claim 1, further comprising:
depositing a film on a substrate in the process chamber prior to providing the fluorine-containing species into the process chamber.
